(19) United States
(12) Patent Application Publication
(10) Pub. No.: US 2011/0272692 A1
(43) Pub. Date: Nov. 10, 2011

(54) SIZE VARIABLE TYPE SEMICONDUCTOR CHIP AND SEMICONDUCTOR PACKAGE USING THE SAME

(75) Inventors: Kwon Whan HAN, Seoul (KR); Hyung Dong LEE, Seoul (KR)

(73) Assignee: HYNIX SEMICONDUCTOR INC., Icheon-si (KR)

(21) Appl. No.: 12/980,984

(22) Filed: Dec. 29, 2010

(30) Foreign Application Priority Data
May 7, 2010 (KR) 10-2010-0043024

(51) Int. Cl. H01L 23/544; H01L 27/02; H01L 23/482; H01L 23/525

(52) U.S. Cl. 257/48; 257/529; 257/528; 257/620; 257/E23.179; 257/E23.149; 257/E23.011; 257/E27.009

(57) ABSTRACT

A size variable semiconductor chip includes a semiconductor chip area formed with a circuit layer and at least one cutting area extending parallel to at least one side of the semiconductor chip area. A plurality of scribe line parts and a plurality of active parts alternately formed with each other in the cutting area.

### CROSS-REFERENCE TO RELATED APPLICATIONS

The present application claims priority to Korean patent application number 10-2010-0043024 filed on May 7, 2010, which is incorporated herein by reference in its entirety.

### BACKGROUND OF THE INVENTION

The present invention relates to a size variable semiconductor chip, a wafer including the same, and a semiconductor package using the same.

Recently, in the electronic industry, miniaturization and low power consumption as well as high performance and multi-functionality have been required. These requirements serve as strong motives for the development of a technology for vertically stacking different kinds of chips in the semiconductor package industry.

In a semiconductor package that is manufactured through such a vertical stacking technology, a large amount of heat may be generated in respective semiconductor chips. This may lead to failure in one or more of the chips in the package unless the package can be cooled.

A conventional vertical stack type semiconductor package may include, for example, a substrate, a non-memory chip mounted to the substrate, at least one memory chip stacked on the non-memory chip, and an encapsulant molded over the non-memory chip and the memory chip.

However, in such a vertical stack type semiconductor package, since the non-memory chip and the memory chip have different sizes, appropriate paths for discharging the heat generated in the respective chips may not be able to be defined. Even in cases where paths can be defined, hot spots may occur where heat is concentrated due to size difference between the non-memory chip and the memory chip.

### BRIEF SUMMARY OF THE INVENTION

An embodiment of the present invention is directed to a size variable semiconductor chip, and a wafer including the same.

Also, an embodiment of the present invention is directed to a semiconductor package using a size variable semiconductor chip that can allow the sizes of different kinds of semiconductor chips to be selectively varied.

In one embodiment of the present invention, a wafer includes: a plurality of semiconductor chip areas formed with circuit layers; and cutting areas extending parallel to at least one sides of the semiconductor chip areas and having a plurality of scribe line parts and a plurality of active parts that are alternately formed with each other.

The wafer may further include additional elements formed in the active parts that are disposed to be separated from the circuit layer.

The wafer may further include fuse circuits interposed between the circuit layer and the additional elements and selectively cut through laser cutting or electrical cutting.

The additional elements may include at least ones of passive elements, active elements and test circuits.

Cutting areas may extend parallel to two sides of the semiconductor chip area, and the plurality of scribe line parts may be formed in each of the cutting areas that extend in two directions.

Cutting areas may extend parallel to four sides of the semiconductor chip area, and the plurality of scribe line parts may be formed in each of the cutting areas that extend in four directions.

In another embodiment of the present invention, a size variable semiconductor chip includes: a semiconductor chip area formed with a circuit layer; and at least one cutting area extending parallel to at least one side of the semiconductor chip area and having a plurality of scribe line parts and a plurality of active parts that are alternately formed with each other, wherein a size of the size variable semiconductor chip is selectively adjusted by being cut along any one of the scribe line parts.

The size variable semiconductor chip may further include additional elements formed in the active parts that are disposed to be separated from the circuit layer.

The size variable semiconductor chip may further include fuse circuits interposed between the circuit layer and the additional elements and selectively cut through laser cutting or electrical cutting.

The additional elements may include at least ones of passive elements, active elements and test circuits.

Cutting areas may extend parallel to two sides of the semiconductor chip area, and the plurality of scribe line parts may be formed in each of the cutting areas that extend in two directions.

Cutting areas may extend parallel to four sides of the semiconductor chip area, and the plurality of scribe line parts may be formed in each of the cutting areas that extend in four directions.

The size variable semiconductor chip may further include through-electrodes formed to pass through the semiconductor chip area and the cutting area.

In another embodiment of the present invention, a semiconductor package includes: a first semiconductor chip having first through-electrodes formed therein; and one or more second semiconductor chips stacked on the first semiconductor chip and having second through-electrodes formed therein to correspond to the first through-electrodes, wherein each of the first and second semiconductor chips includes a semiconductor chip area formed with a circuit layer, and at least one cutting area extending parallel to at least one side of the semiconductor chip area and having a plurality of scribe line parts and a plurality of active parts that are alternately formed with each other, and wherein a size of each of the first and second semiconductor chips is selectively adjusted by being cut along any one of the scribe line parts.

The semiconductor package may further include additional elements formed in the active parts that are disposed to be separated from the circuit layer.

The first semiconductor chip may have a size greater than the stacked second semiconductor chips.

The stacked second semiconductor chips may have different sizes from one another.

An uppermost second semiconductor chip of the stacked second semiconductor chips may have a size corresponding to that of the first semiconductor chip.

The first through-electrodes may be formed in the semiconductor chip area and the cutting area of the first semiconductor chip, and the second through-electrodes may be formed in the semiconductor chip areas and the cutting areas of the second semiconductor chips.

The semiconductor package may further include a substrate supporting the first and second semiconductor chips.

The semiconductor package may further include a third semiconductor chip disposed between the substrate and the first semiconductor chip and having third through-electrodes formed therein to correspond to the first through-electrodes.

In another embodiment of the present invention, a semiconductor package includes: a substrate; a first semiconductor chip mounted onto the substrate and having first through-electrodes formed therein; and one or more second semiconductor chips stacked on the first semiconductor chip and having second through-electrodes formed therein to correspond to the first through-electrodes, wherein each of the second semiconductor chips includes a semiconductor chip area formed with a circuit layer, and at least one cutting area extending parallel to at least one side of the semiconductor chip area and having a plurality of scribe line parts and a plurality of active parts that are alternately formed with each other, and wherein each of the second semiconductor chips is cut along any one of the scribe line parts and has a size corresponding to that of the first semiconductor chip.

The semiconductor package may further include a heat dissipation member formed to cover the substrate including the first semiconductor chip and the stacked second semiconductor chips.

The semiconductor package may further include a heat transfer adhesive layer interposed between the heat dissipation member and an uppermost second semiconductor chip of the stacked second semiconductor chips.

The first semiconductor chip may include a non-memory chip, and the second semiconductor chips may include memory chips.

Each of the second semiconductor chips may have heat dissipation patterns that are formed in the semiconductor chip area and the cutting area to be electrically isolated from the second through-electrodes and the additional elements.

### BRIEF DESCRIPTION OF THE DRAWINGS

FIG. 1 is a plan view illustrating a wafer in accordance with an embodiment of the present invention.

FIG. 2 is an enlarged plan view illustrating part A of FIG. 1.

FIGS. 3 and 4 are plan views illustrating portions of wafers in accordance with various embodiments of the present invention.

FIG. 5 is a cross-sectional view illustrating a size variable semiconductor chip in accordance with an embodiment of the present invention.

FIG. 6 is a plan view illustrating the size variable semiconductor chip in accordance with the embodiment of the present invention shown in FIG. 5.

FIG. 7 is a cross-sectional view illustrating a semiconductor package in accordance with another embodiment of the present invention.

FIG. 8 is an enlarged cross-sectional view illustrating a second semiconductor chip of the semiconductor package shown in FIG. 7.

FIG. 9 is a cross-sectional view illustrating in detail the semiconductor package shown in FIG. 7.

FIG. 10 is a cross-sectional view illustrating a semiconductor package in accordance with another embodiment of the present invention.

FIG. 11 is an enlarged cross-sectional view illustrating a second semiconductor chip of the semiconductor package shown in FIG. 10.

### DESCRIPTION OF SPECIFIC EMBODIMENTS

Specific embodiments of the present invention will be described in detail with reference to the accompanying drawings.

It is to be understood that the drawings are not necessarily to scale and in some instances proportions may have been exaggerated in order to more clearly depict certain features of the invention.

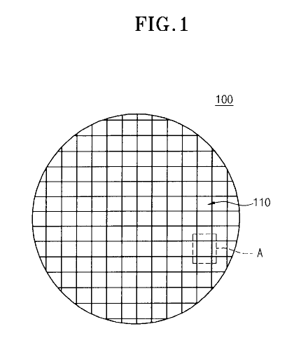

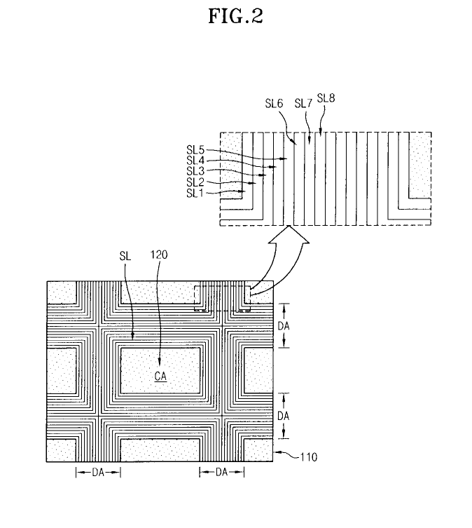

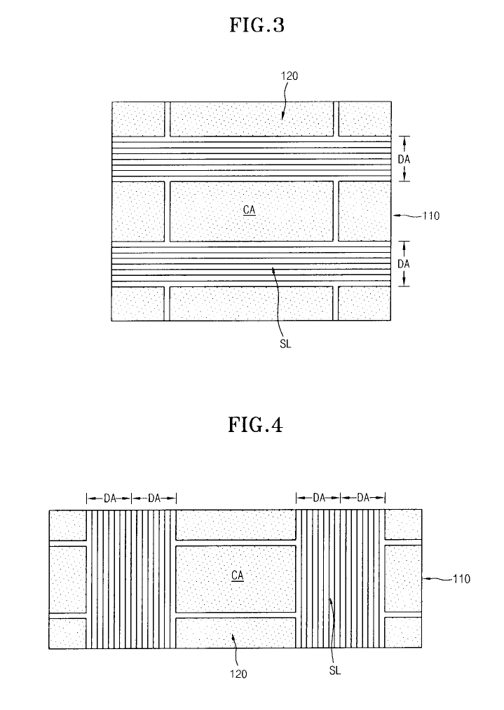

FIG. 1 is a plan view illustrating a wafer in accordance with an embodiment of the present invention, and FIG. 2 is an enlarged plan view illustrating the part A of FIG. 1. FIGS. 3 and 4 are plan views illustrating portions of wafers in accordance with various embodiments of the present invention.

Referring to FIGS. 1 and 2, a wafer 100 in accordance with an embodiment of the present invention includes a wafer body 110 and a circuit layer 120. The wafer 100 can further include additional elements (not shown).

The wafer body 110 has a plurality of semiconductor chip areas CA and cutting areas DA which may extend parallel to at least one sides of the respective semiconductor chip areas CA and in each of which a plurality of scribe line parts SL and a plurality of active parts (not shown) are alternately formed.

The circuit layer 120 is formed in the respective semiconductor chip areas CA of the wafer body 110. The circuit layer 120 includes a data storage unit (not shown), a data processing unit (not shown), and bonding pads (not shown). The data storage unit stores data, and the data processing unit processes the data stored in the data storage unit. The bonding pads can be connected with the data storage unit and/or the data processing unit.

The additional elements are formed in the active parts of each cutting area DA that are separated from the circuit layer 120. The additional elements will be described later in detail.

FIG. 2 illustrates an example of the wafer 100 which has eight scribe line parts SL1, SL2, SL3, SL4, SL5, SL6, SL7 and SL8 in each cutting area DA which may extend parallel to each side of each semiconductor chip area CA. Each semiconductor chip area CA has a two-dimensional shape such as, for example, a rectangular shape when viewed from the top, and four cutting areas DA that define the corresponding semiconductor chip area CA.

The scribe line parts SL disposed in the cutting area DA can be placed, for example, in such a way as to be spaced apart from one another by a predetermined interval. The scribe line parts SL can be placed at regular intervals or irregular intervals.

Referring to FIG. 3, one cutting area DA can extend parallel to one side of each semiconductor chip area CA. In this case, a plurality of scribe line parts SL may be disposed in the cutting area DA that extends parallel to the one side of each semiconductor chip area CA.

Referring to FIG. 4, two cutting areas DA can extend parallel to two sides of each semiconductor chip area CA. In this case, a plurality of scribe line parts SL may be disposed in each of the cutting areas DA which extend parallel to two sides of each semiconductor chip area CA. The two sides may be parallel to each other or perpendicular to each other. FIG. 4 illustrates an example in which the cutting areas DA extend parallel to two sides of each semiconductor chip area CA, where the two sides are parallel to each other. While not shown in a drawing, cutting areas DA can extend parallel to three sides of each semiconductor chip area CA. In this case, a plurality of scribe line parts SL may be disposed in each of the cutting areas DA which may extend parallel to the three sides of each semiconductor chip area CA.

In the wafer 100 constructed as mentioned above, the size of each semiconductor chip can be selectively adjusted by cutting the wafer body 110 into a chip level along one scribe line part SL among the scribed line parts SL disposed in each cutting area DA.

This will be described below in detail with reference to the attached drawings.

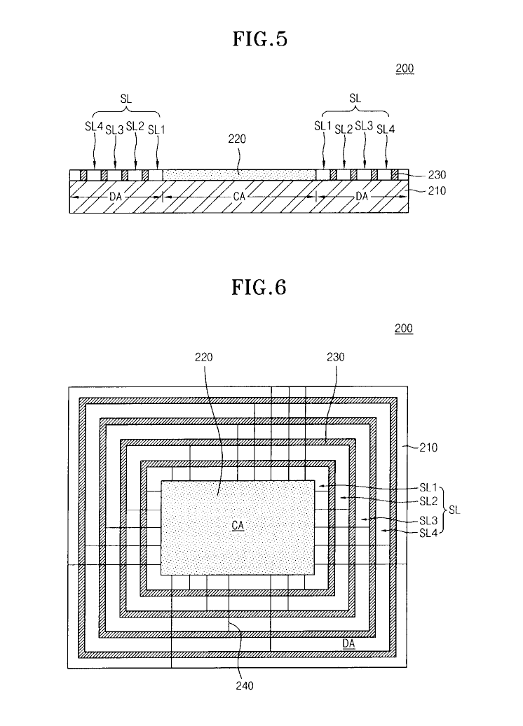

FIG. 5 is a cross-sectional view illustrating a size variable semiconductor chip in accordance with an embodiment of the present invention, and FIG. 6 is a plan view illustrating the size variable semiconductor chip in accordance with the embodiment of the present invention shown in FIG. 5.

Referring to FIGS. 5 and 6, a size variable semiconductor chip 200 in accordance with another embodiment of the present invention includes a semiconductor chip body 210 and a circuit layer 220. The size variable semiconductor chip 200 can further include additional elements 230 and fuse circuits 240.

The semiconductor chip body 210 may comprise a semiconductor chip area CA and cutting areas DA which may extend parallel to one or more sides of the semiconductor chip area CA and in each of which a plurality of scribe line parts SL and a plurality of active parts (not shown) are alternately formed. The scribe line parts SL may be defined as portions of the semiconductor chip body 210 which may be cut by a saw blade, and the active parts may be defined as portions of the semiconductor chip body 210 that are disposed between the scribe line parts SL.

The circuit layer 220 is formed in the semiconductor chip area CA of the semiconductor chip body 210. The circuit layer 220 includes a data storage unit (not shown), a data processing unit (not shown), and bonding pads (not shown). The data storage unit stores data, and the data processing unit processes the data stored in the data storage unit. The bonding pads can be connected with the data storage unit and/or the data processing unit.

The additional elements 230 are formed in the active parts of each cutting area DA which are separated from the circuit layer 220. The additional element 230 can include at least one of a passive element, an active element and a test circuit. For example, the passive element may include a resistor, a capacitor or an inductor, and the active element may include a transistor.

The fuse circuits 240 are disposed between the circuit layer 220 and the additional elements 230. Each fuse circuit 240 may comprise a first end and a second end. The first and second ends of the fuse circuits 240 may be respectively connected to the circuit layer 220 and the additional elements 230. The fuse circuits 240 may be selectively cut, for example, through laser cutting or electrical cutting to form open circuits.

The additional elements 230 and the fuse circuits 240 may be formed in such a manner that they can be independently driven even when the semiconductor chip body 210 is cut along any one of the scribe line parts SL in each cutting area DA. In particular, since the fuse circuits 240 may be designed to be selectively cut through laser cutting or electrical cutting, the capacity of the additional elements 230 can be selectively changed as the occasion demands.

The fuse circuits 240 may be selectively cut at a wafer or at a chip level.

The size variable type semiconductor chip 200 in accordance with an embodiment of the invention may be any one of semiconductor chips which may be individualized from the wafer 100 shown in FIG. 2. Since the size variable semiconductor chip 200 can be cut along any of the scribe lines SL, a semiconductor chip having a desired size can be obtained depending upon a design object or as the occasion demands. For example, FIG. 5 illustrates the size variable semiconductor chip 200 that is cut along the fifth scribe lines parts SL5 shown in FIG. 2.

Accordingly, in an embodiment of the invention, the size of a semiconductor chip can be selectively varied by cutting any one of a plurality of scribe line parts SL disposed in each cutting area, and the circuit layer 220 can be connected to specific additional elements by selectively cutting specific fuse circuits 240.

Hereafter, semiconductor packages in accordance with other embodiments of the present invention will be described with reference to the attached drawings.

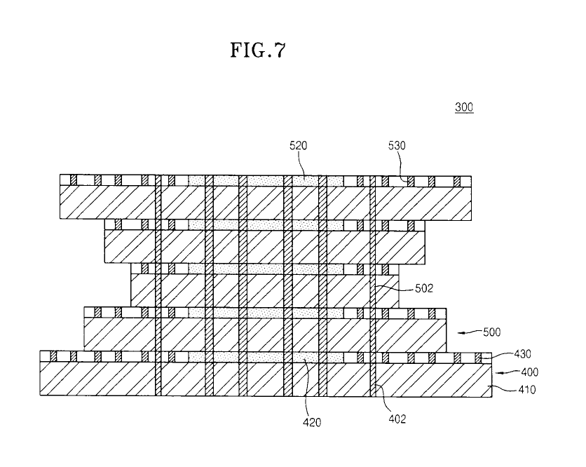

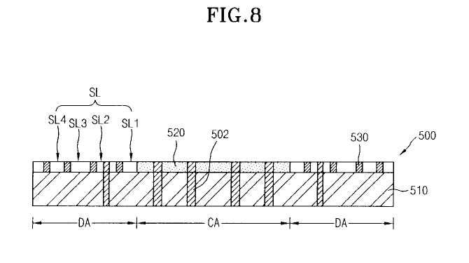

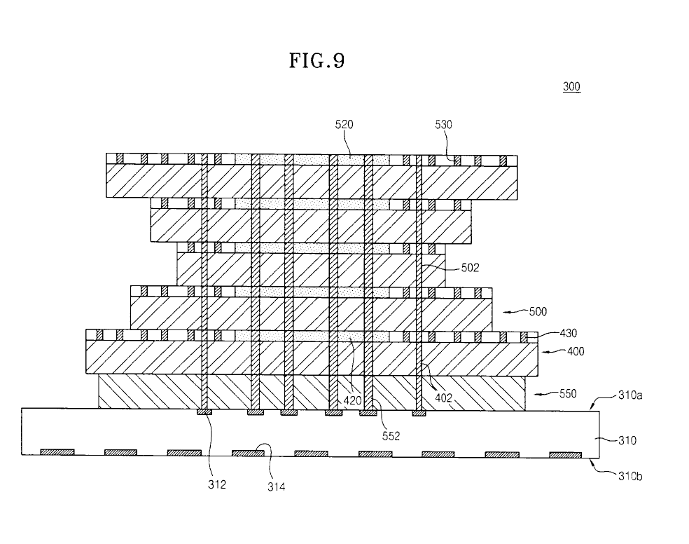

FIG. 7 is a cross-sectional view illustrating a semiconductor package in accordance with another embodiment of the present invention, FIG. 8 is an enlarged cross-sectional view illustrating a second semiconductor chip of the semiconductor package shown in FIG. 7, and FIG. 9 is a cross-sectional view illustrating in detail the semiconductor package in accordance with the embodiment of the present invention shown in FIG. 7.

Referring to FIGS. 7 and 8, a semiconductor package 300 in accordance with another embodiment of the present invention includes a first semiconductor chip 400 and one or more second semiconductor chips 500 that are stacked on the first semiconductor chip 400.

The first semiconductor chip 400 has first through-electrodes 402 formed therein. Each of the second semiconductor chips 500 has second through-electrodes 502 formed therein to correspond to the first through-electrodes 402. One or more second semiconductor chips 500 are stacked on the first semiconductor chip 400. The first and second semiconductor chips 400 and 500 can include memory chips.

The first and second semiconductor chips 400 and 500 include semiconductor chip bodies 410 and 510 having semiconductor chip areas CA and cutting areas DA which extend parallel to at least one sides of the semiconductor chip areas CA. The chip bodies 400 and 500 also comprise a plurality of scribe line parts SL and a plurality of active parts 430 and 530 that are alternately formed, and circuit layers 420 and 520 formed in the semiconductor chip areas CA of the semiconductor chip bodies 410 and 510.

The first and second semiconductor chips 400 and 500 are selectively adjusted in their sizes by being cut along any one of the scribe line parts SL in each cutting area DA. The first and second semiconductor chips 400 and 500 can further include additional elements 430 and 530 which are alternately formed in the active parts with the scribe line parts SL. Each of the additional elements 430 and 530 can include at least one of a passive element, an active element and a test circuit. For example, the passive element includes a resistor, a capacitor or an inductor, and the active element includes a transistor.

The first semiconductor chip 400 can be adjusted to have a size that is greater than the stacked second semiconductor chips 500, and the stacked second semiconductor chips 500 can be adjusted to have different sizes. All the stacked second semiconductor chips 500 can have different sizes from one another, or some of the stacked second semiconductor chips 500 can have the same size and the remaining stacked second semiconductor chips 500 can have different sizes from one another.

The uppermost second semiconductor chip 500 among the stacked second semiconductor chips 500 may have a size corresponding to that of the first semiconductor chip 400. The first and second semiconductor chips 400 and 500 may also be adjusted to selectively have various sizes.

The first through-electrodes 402 are formed in the semiconductor chip area CA and the cutting areas DA of the first semiconductor chip 400, and the second through-electrodes 502 are formed in the semiconductor chip area CA and the cutting areas DA of the second semiconductor chips 500.

FIG. 9 is a cross-sectional view illustrating in detail the semiconductor package shown in FIG. 7. Referring to FIG. 9, the semiconductor package 300 in accordance with an embodiment of the present invention can further include a substrate 310 and a semiconductor chip 550 in addition to the semiconductor chips 400 and 500.

The substrate 300 supports the semiconductor chips 400, 500, and the semiconductor chip 550. The substrate 310 has a first surface 310a and a second surface 310b. Bond fingers 312 are disposed on the first surface 310a, and circuit patterns (not shown) including ball lands 314 are disposed on the second surface 310b. The bond fingers 312 may be disposed along the center portions or adjacent to the edges of the first surface 310a.

The semiconductor chip 550 may be interposed between the substrate 310 and the semiconductor chip 400, and may comprise third through-electrodes 552 that are disposed to correspond to the first through-electrodes 402. The third semiconductor chip 550 may include a non-memory chip. The third through-electrodes 552 may be disposed to correspond to the first through-electrodes 402 and the bond fingers 312 so that the semiconductor chip 550 may be electrically connected with the semiconductor chip 400 and the substrate 310.

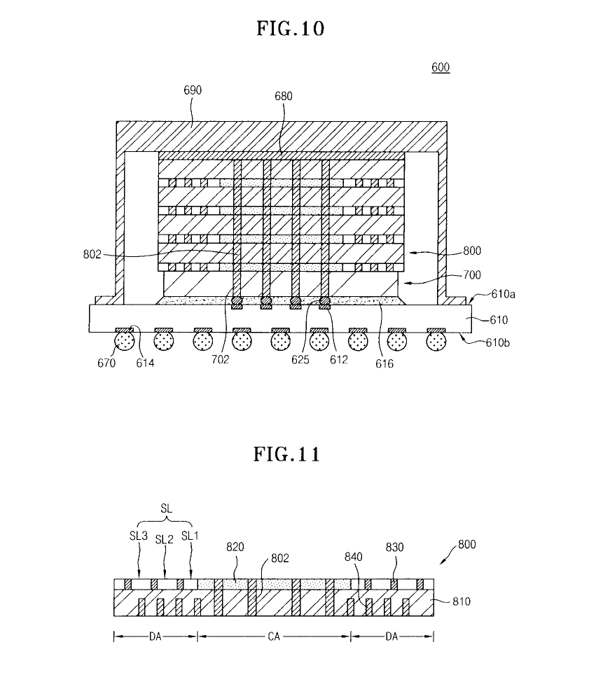

FIG. 10 is a cross-sectional view illustrating a semiconductor package in accordance with an embodiment of the present invention, and FIG. 11 is an enlarged cross-sectional view illustrating a second semiconductor chip of the semiconductor package shown in FIG. 10.

Referring to FIGS. 10 and 11, a semiconductor package 600 in accordance with another embodiment of the present invention includes a substrate 610, a semiconductor chip 700, an underfill member 616, and semiconductor chips 800. The semiconductor package 600 can further include a heat transfer adhesive layer 680, and a heat dissipation member 690.

The substrate 610 has a first surface 610a and a second surface 610b. Bond fingers 612 may be disposed on the first surface 610a, and circuit patterns (not shown) including ball lands 614 may be disposed on the second surface 610b. The bond fingers 612 can be disposed along the center portions or adjacent to the edges of the first surface 610a of the substrate 610.

The semiconductor chip 700 is mounted to the first surface 610a of the substrate 610 and has first through-electrodes 702 formed therein. The first through-electrodes 702 can be disposed at positions corresponding to the bond fingers 612. In this case, the first through-electrodes 702 can be electrically connected with the bond fingers 612 by, for example, connection members 625. The semiconductor chip 700 may include a non-memory chip, and the connection members 625 may include solders or bumps. The external connection terminals 670 may be attached to the ball lands 614.

The underfill member 616 is formed in the space between the substrate 610 and the semiconductor chip 700 and may protect the semiconductor chip 700 from external shocks or vibrations.

One or more semiconductor chips 800 may be stacked on the semiconductor chip 700. The semiconductor chips 800 may include memory chips and have second through-electrodes 802 formed therein. The second through-electrodes 802 can be disposed at positions corresponding to the first through-electrodes 702. In this case, the semiconductor chip 700 may be electrically connected to the second semiconductor chips 800 by the first through-electrodes 702 and the second through-electrodes 802.

Each of the semiconductor chips 800 includes a semiconductor chip body 810 having a semiconductor chip area CA and cutting areas DA which extend parallel to one or more sides of the semiconductor chip area CA and in each of which a plurality of scribe line parts SL and a plurality of active parts (not shown) are alternately formed, and a circuit layer 820 formed in the semiconductor chip area CA of the semiconductor chip body 810.

Referring to FIG. 11, a semiconductor chip 800 may further include additional elements 830 and heat dissipation patterns 840. The additional elements 830 are disposed in the active parts which are formed alternately with the scribe line parts SL, and the heat dissipation patterns 840 are formed in the semiconductor chip area CA and the cutting areas DA of the semiconductor chip body 810. The heat dissipation patterns 840 are disposed in the semiconductor chip body 810 and have island structures in which the heat dissipation patterns 840 are electrically isolated from the second through-electrodes 802 and the additional elements 830.

Referring again to FIGS. 10 and 11, the sizes of the stacked semiconductor chips 800 may be the same or different from one another.

FIGS. 10 and 11 show stacked semiconductor chips 800 as being cut along fourth scribe line parts (see SL4 of FIG. 2). However, this is for exemplary purposes, and it should be understood that a cut may be made along any scribe line part.

The heat dissipation member 690 is formed to cover at least the first surface 610a of the substrate 610 including the semiconductor chip 700 and the stacked semiconductor chips 800. The heat dissipation member 690 can be formed from material that have good heat conductivity such as, for example, copper, aluminum, titanium, and other materials or alloys thereof.

The heat transfer adhesive layer 680 is interposed between the heat dissipation member 690 and the uppermost of the stacked semiconductor chips 800. The heat transfer adhesive layer 680 may be formed of a material capable of quickly transferring heat generated by the semiconductor chips 700 and 800. The heat transfer adhesive layer 680 may include material such as, for example, a TIM (thermal interface material).

As is apparent from the above description of various embodiments of the present invention, the size of a semiconductor chip can be varied by selectively cutting any one of a plurality scribe line parts which are disposed in a cutting area.

Also, in various embodiments of the present invention, due to the fact that additional elements that are electrically connected by a circuit layer are formed in active parts that are disposed in the cutting area, electrical reliability of the circuit layer can be improved.

Furthermore, in various embodiments of the present invention, since the size of a size variable semiconductor chip can be varied to be similar to that of a non-memory chip, a semiconductor package can be manufactured to have uniform heat dissipation paths even when different kinds of chips are vertically stacked. Accordingly, various embodiments of the present invention may improve heat dissipation efficiency when stacking different kinds of chips.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed:

1. A size variable semiconductor chip comprising:
a semiconductor chip area formed with a circuit layer; and
at least one cutting area extending parallel to at least one side of the semiconductor chip area and having a plurality of scribe line parts and a plurality of active parts which are alternately formed with each other,
wherein a size of the size variable semiconductor chip is selectively adjusted by cutting along any one of the scribe line parts.

2. The size variable semiconductor chip according to claim 1, further comprising:
additional elements formed in the active parts.

3. The size variable semiconductor chip according to claim 2, further comprising:
at least one fuse circuit interposed between the circuit layer and each of the additional elements.

4. The size variable semiconductor chip according to claim 2, wherein the additional elements include at least one of passive elements, active elements and test circuits.

5. The size variable semiconductor chip according to claim 1, wherein cutting areas extend parallel to two sides of the semiconductor chip area, and the plurality of scribe line parts are formed in each of the cutting areas.

6. The size variable semiconductor chip according to claim 1, wherein cutting areas extend parallel to four sides of the semiconductor chip area, and the plurality of scribe line parts are formed in each of the cutting areas.

7. The size variable semiconductor chip according to claim 1, further comprising:
through-electrodes formed to pass through the semiconductor chip area and the cutting area.

8. A semiconductor package comprising:
a first semiconductor chip having first through-electrodes formed therein; and
one or more second semiconductor chips stacked on the first semiconductor chip and having second through-electrodes formed therein to correspond to the first through-electrodes,
wherein each of the first and second semiconductor chips includes a semiconductor chip area formed with a circuit layer, and at least one cutting area extending parallel to at least one side of the semiconductor chip area and having a plurality of scribe line parts and a plurality of active parts which are alternately formed with each other, and
wherein a size of each of the first and second semiconductor chips is selectively adjusted by being cut along any one of the scribe line parts.

9. The semiconductor package according to claim 8, further comprising:
additional elements formed in the active parts which are disposed to be separated from the circuit layer.

10. The semiconductor package according to claim 8, wherein the first semiconductor chip has a size greater than each of the stacked second semiconductor chips.

11. The semiconductor package according to claim 8, wherein at least one of the stacked second semiconductor chips has a different size from the others.

12. The semiconductor package according to claim 8, wherein an uppermost second semiconductor chip of the stacked second semiconductor chips has a size corresponding to that of the first semiconductor chip.

13. The semiconductor package according to claim 8, wherein the first through-electrodes are formed in the semiconductor chip area and the cutting area of the first semiconductor chip, and the second through-electrodes are formed in the semiconductor chip areas and the cutting areas of the second semiconductor chips.

14. The semiconductor package according to claim 8, further comprising:
a substrate supporting the first and second semiconductor chips.

15. The semiconductor package according to claim 14, further comprising:
a third semiconductor chip disposed between the substrate and the first semiconductor chip and having third through-electrodes formed therein to correspond to the first through-electrodes.

16. A semiconductor package comprising:
a first semiconductor chip mounted onto a substrate and having first through-electrodes formed therein; and
one or more second semiconductor chips stacked on the first semiconductor chip and having second through-electrodes formed therein to correspond to the first through-electrodes,
wherein each of the second semiconductor chips includes a semiconductor chip area formed with a circuit layer, and at least one cutting area extending parallel to at least one side of the semiconductor chip area and having a plurality of scribe line parts and a plurality of active parts which are alternately formed with each other, and
wherein each of the second semiconductor chips is cut along any one of the scribe line parts and has a size corresponding to that of the first semiconductor chip.

17. The semiconductor package according to claim 16, further comprising:
a heat dissipation member formed to cover the substrate including the first semiconductor chip and the stacked second semiconductor chips.

18. The semiconductor package according to claim 17, further comprising:
a heat transfer adhesive layer interposed between the heat dissipation member and an uppermost second semiconductor chip of the stacked second semiconductor chips.

19. The semiconductor package according to claim 16, wherein the first semiconductor chip includes a non-memory chip, and the second semiconductor chips include memory chips.

20. The semiconductor package according to claim 16, wherein each of the second semiconductor chips has heat dissipation patterns which are formed in the semiconductor chip area and the cutting area to be electrically isolated from the second through-electrodes and the additional elements.
